(19) United States
(12) Patent Application Publication
(10) Pub. No.: US 2024/0396527 A1
(43) Pub. Date: Nov. 28, 2024

(54) ACOUSTIC WAVE DEVICES AND MODULES COMPRISING SAME

(71) Applicant: Sanan Japan Technology Corporation, Tokyo (JP)

(72) Inventors: Eiji KUWAHARA, Tokyo (JP); Shinichi SHIOI, Tokyo (JP)

(73) Assignee: Sanan Japan Technology Corporation, Tokyo (JP)

(21) Appl. No.: 18/674,324

(22) Filed: May 24, 2024

(30) Foreign Application Priority Data
May 26, 2023 (JP) 2023-086582

(51) Int. Cl. H03H 9/72; H03H 9/02; H03H 9/64

(52) U.S. Cl. CPC H03H 9/725; H03H 9/02559; H03H 9/6483

(57) ABSTRACT

An acoustic wave device includes a band pass filter having a plurality of series resonators and a plurality of parallel resonators. The plurality of series resonators include a first series resonator and a second series resonator. The first series resonator has a first attenuation pole and a second attenuation pole having an attenuation amount that is less than or equal to half of that of the first attenuation pole. The second series resonator includes a third attenuation pole and a fourth attenuation pole. The third attenuation pole and the fourth attenuation pole has an attenuation amount less than that of the first attenuation pole and greater than that of the second attenuation pole.

### CROSS-REFERENCE TO RELATED APPLICATION(S)

This application claims priority to Japanese Application No. 2023-086582, filed May 26, 2023, which are incorporated herein by reference, in their entirety, for any purpose.

### BACKGROUND OF THE INVENTION

### Field of the Invention

The present disclosure relates to an acoustic wave device and a module including the acoustic wave device, particularly relates to a duplexer.

### Background Art

Recent technological developments have made mobile communication terminals as typified by smartphones remarkably miniaturized and lightened. The acoustic wave device used in such mobile communication terminals is capable of miniaturization. In addition, a communication system that simultaneously transmits and receives data is rapidly increasing as a mobile communication system. As a result, a demand for a duplexer is rapidly increasing.

Along with changes in mobile communication systems, requirement specifications for acoustic wave devices have become more stringent. For example, more miniaturized acoustic wave devices are required compared to that in the conventional technique. Moreover, the acoustic wave device with improved isolation characteristics is required.

Patent Document 1 (WO2010/073377) discloses the technology for connecting a capacitive element in parallel with a reception filter in order to improve isolation characteristics.

However, the acoustic wave device described in Patent Document 1 increases insertion loss and hinders miniaturization of acoustic wave devices since it requires additional elements.

### SUMMARY OF THE INVENTION

Some examples described herein may address the above-described problems. Some examples described herein may have an object to provide an acoustic wave device capable of improving isolation characteristics having steep characteristics without increasing insertion loss or using an additional element, and a module including the acoustic wave device.

In some examples, an acoustic wave device includes a band pass filter having a plurality of series resonators and a plurality of parallel resonators. The plurality of series resonators include a first series resonator and a second series resonator. The first series resonator has a first attenuation pole and a second attenuation pole that is less than or equal to half of the first attenuation pole. The second series resonator include a third attenuation pole and a fourth attenuation pole. The third attenuation pole and the fourth attenuation pole include the acoustic wave device that has an attenuation amount less than that of the first attenuation pole and greater than that of the second attenuation pole. It should be noted that the first series resonator and the second series resonator need not be arranged in this order in a circuit manner.

### BRIEF DESCRIPTION OF THE DRAWING

FIG. 1 is a longitudinal sectional view of an acoustic wave device according to a first embodiment.

FIG. 2 is a diagram illustrating an example of an acoustic wave element (resonator) of the acoustic wave device according to the first embodiment.

FIG. 3 is a diagram illustrating an example of a duplexer formed on a device chip 25 of the acoustic wave device according to the first embodiment.

FIG. 4 is a diagram illustrating resonance characteristics of series resonators S1 to S5 according to the first embodiment.

FIG. 5 is a diagram illustrating attenuation characteristics of the acoustic wave device of the first embodiment and a comparative example.

FIG. 6 is a diagram illustrating isolation characteristics of the acoustic wave device according to the first embodiment and the comparative example.

FIG. 7 is a diagram illustrating an insertion loss of the acoustic wave device of first embodiment and the comparative example.

FIG. 8 is a longitudinal sectional view of a module to which the acoustic wave device according to a second embodiment is applied.

### DETAILED DESCRIPTION

The embodiments will be described with reference to the accompanying drawings. In the drawings, the same or corresponding parts are denoted by the same reference numerals. Duplicate descriptions of such portions may be simplified or omitted.

### First Embodiment

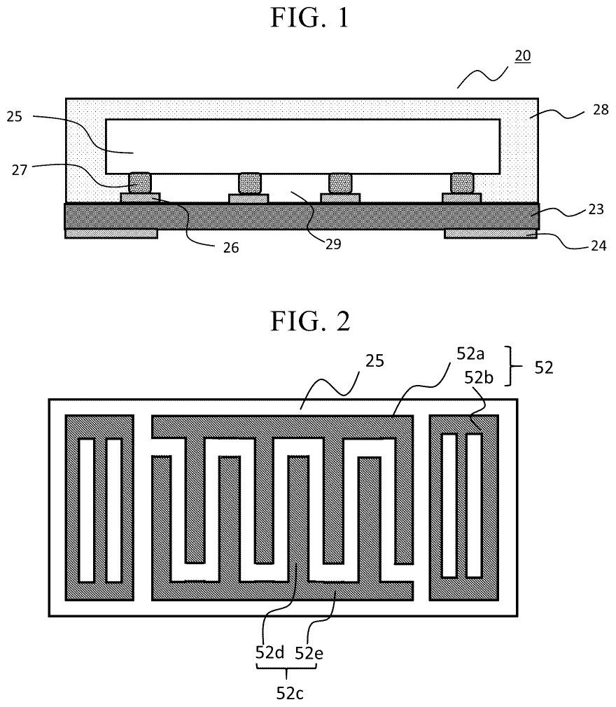

FIG. 1 is a longitudinal sectional view of an acoustic wave device according to a first embodiment.

As shown in FIG. 1, an acoustic wave device 20 includes a wiring substrate 23, an external connection terminal 24, a device chip 25, an electrode pad 26, bumps 27, and a sealing portion 28.

For example, the wiring substrate 23 is a multilayer substrate made of resin. For example, the wiring substrate 23 is a low-temperature co-fired ceramic (LTCC) multilayer substrate includes a plurality of dielectric layers.

The plurality of external connection terminals 24 are formed on the lower surface of the wiring substrate 23.

The plurality of electrode pads 26 are formed on the main surface of the wiring substrate 23. The electrode pad 26 is formed of, for example, copper or an alloy containing copper. The electrode pad 26 has a thickness of 10 μm to 20 μm for example.

The bumps 27 are formed on the upper surfaces of the electrode pads 26. For example, the bump 27 is made of gold. For example, the height of the bump 27 is 10 μm to 50 km.

An air gap 29 is formed between the wiring substrate 23 and the device chip 25.

The device chip 25 is mounted on the wiring substrate 23 via the bumps 27 by flip-chip bonding. The device chip 25 is electrically connected to the plurality of electrode pads 26 via the plurality of bumps 27.

The device chip 25 is, for example, a surface acoustic wave device chip. The device chip 25 includes, for example, a piezoelectric substrate formed of a piezoelectric material. The piezoelectric substrate is a substrate formed of a piezoelectric single crystal such as lithium tantalate, lithium niobate, or quartz.

The piezoelectric substrate has a thickness of 100 μm to 300 μm for example. According to another example, the piezoelectric substrate is a substrate formed of piezoelectric ceramics.

In yet another example, the device chip 25 is a substrate in which a piezoelectric substrate and a support substrate are bonded to each other. The support substrate is, for example, a substrate formed of sapphire, silicon, alumina, spinel, quartz or glass. In this case, the piezoelectric substrate can have a thickness, for example, 0.3 μm to 5 μm.

A plurality of acoustic wave elements 52 are formed on the piezoelectric substrate. For example, a transmitting filter or a reception filter including the plurality of acoustic wave elements 52 is formed on the main surface of the device chip 25.

According to another example, a duplexer including the transmitting filter and the reception filter is formed on the main surface of the device chip 25.

The transmitting filter is formed so that an electrical signal of a desired frequency band can pass through. The transmitting filter is, for example, a ladder-type filter including a plurality of series resonators and a plurality of parallel resonators.

The reception filter is formed so that an electrical signal of a desired frequency band can pass through. The reception filter is, for example, a ladder-type filter.

The sealing portion 28 is formed to cover the device chip 25. The sealing portion 28 is formed of, for example, an insulator such as a synthetic resin. The sealing portion 28 is formed of metal for example.

In case the sealing portion 28 is formed of a synthetic resin, the synthetic resin is an epoxy resin, polyimide, or the like. Preferably, the sealing portion 28 is formed of an epoxy resin using a low temperature curing process using an epoxy resin.

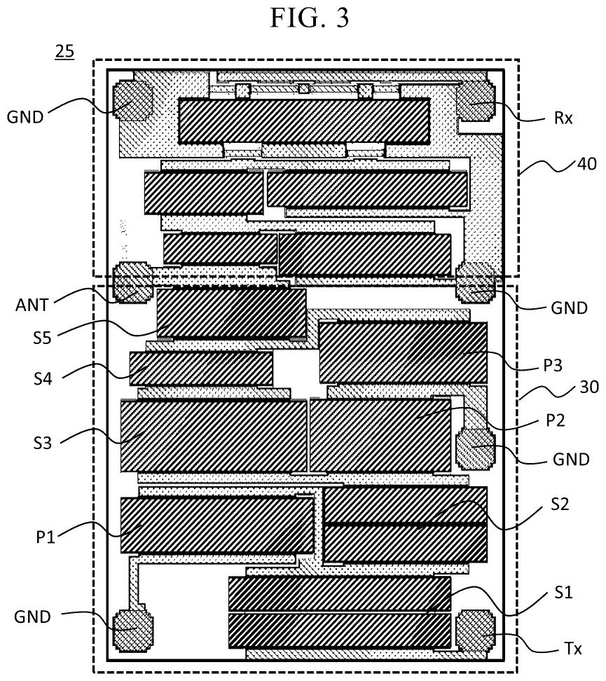

Next, the example of the acoustic wave elements 52 formed on the device chip 25 is described by FIG. 2. FIG. 2 is a diagram illustrating an example of an acoustic wave element (resonator) of the acoustic wave device according to the first embodiment.

As shown in FIG. 2, an IDT (Interdigital Transducer) 52a and a pair of reflectors 52b are formed on the main surface of the device chip 25. The IDT 52a and the pair of reflectors 52b are provided so as to excite acoustic waves (mainly SH waves).

The IDT electrodes 52a and the pair of reflectors 52b are made of an alloy of aluminum and copper for example. The IDT electrodes 52a and the pair of reflectors 52b are made of a suitable metal such as aluminum, molybdenum, iridium, tungsten, cobalt, nickel, ruthenium, chromium, strontium, titanium, palladium, or silver, or an alloy thereof.

The IDT electrodes 52a and the pair of reflectors 52b are formed of a laminated metal film in which a plurality of metal layers are laminated. The thicknesses of the IDT electrodes 52a and the pair of reflectors 52b is 150 nm to 450 nm for example.

The IDT electrodes 52a include a pair of comb-shaped electrodes 52c. The pair of comb-shaped electrodes 52c are opposed to each other. The comb-shaped electrodes 52c include a plurality of electrode fingers 52d and a busbar 52e.

The plurality of fingers 52d are longitudinally aligned. The busbar 52e connects the plurality of fingers 52d.

One of the pair of reflectors 52b adjoins one side of the IDT electrodes 52a. The other of the pair of reflectors 52b adjoins the other side of IDT electrodes 52a.

Next, the example of the acoustic wave device according to the first embodiment is described by FIG. 3. FIG. 3 is a diagram illustrating an example of the duplexer formed on the device chip 25 of the acoustic wave device according to the first embodiment.

As shown in FIG. 3, a transmitting filter 30 as a band pass filter is formed on the device chip 25. The transmitting filter 30 includes an antenna pad ANT, a transmitting pad Tx, and a ground pad GND. The pass band of the transmitting filter 30 of the acoustic wave device in the first embodiment is 880 MHz to 915 MHz.

Further, the transmitting filter 30 includes the plurality of series resonators, for example, a series resonator S1 arranged at a first location from the transmitting pad Tx, a series resonator S2 arranged at a second location from the transmitting pad Tx, a series resonator S3 arranged at a third location from the transmitting pad Tx, a series resonator S4 arranged at a fourth location from the transmitting pad Tx, and a series resonator S5 arranged at a fifth location from the transmitting pad Tx. As shown in FIG. 3, the series resonator S1 and the series resonator S2 are each divided into resonators having the same frequency properties, and are treated as one series resonator in a set. Since a parallel resonator is not arranged between the series resonator S3 and the series resonator S4, the series resonator S3 and the series resonator S4 look like split resonators. However, they are treated as separate series resonators due to different frequency characteristics.

Further, the transmitting filter 30 is a ladder-type filter including a plurality of parallel resonators, for example, a parallel resonator P1 arranged at a first location, a parallel resonator P2 arranged at a second location, and a parallel resonator P3 arranged at a third location from the transmitting pad Tx.

As shown in FIG. 3, a reception filter 40 as a band pass filter is formed on the device chip 25. The reception filter 40 includes the antenna pad ANT, a reception pad Rx, and a ground pad GND. The antenna pad ANT is shared with the transmitting filter 30. The pass band of the reception filter 40 of the acoustic wave device in the first embodiment is 925 MHz to 960 MHz.

Each of the bumps 27 is disposed on a respective one of the antenna pad ANT, the transmitting pad Tx, the reception pad Rx, and the ground pad GND, and is electrically connected to a respective one of the bump pads 26 mounted on the wire substrate 23.

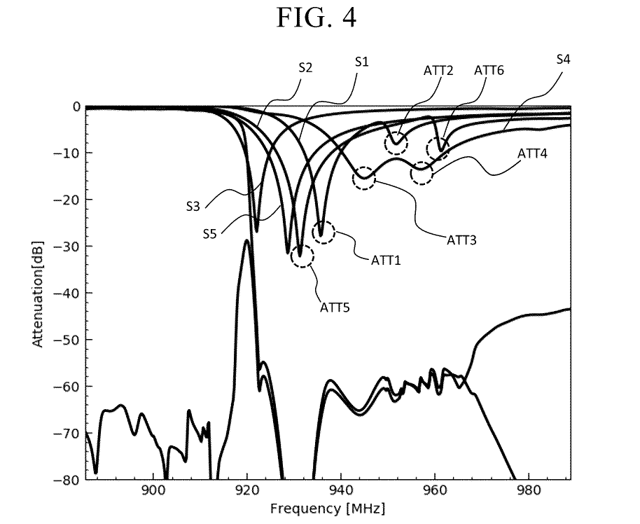

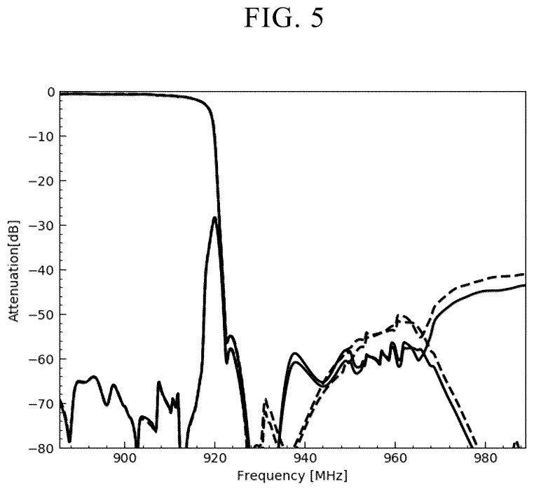

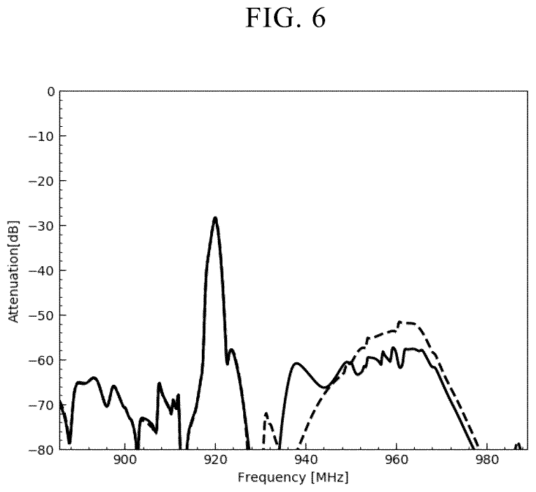

FIG. 4 is a diagram illustrating resonance characteristics of the series resonators S1 to S5 according to the first embodiment. Note that FIG. 4 includes a solid line which is included in FIG. 5 and FIG. 6 described later.

As shown in FIG. 4, the series resonator S1 has resonance characteristics including a first attenuation pole ATT1 and a second attenuation pole ATT2 having an attenuation amount less than or equal to half of the attenuation amount of the first attenuation pole ATT1. In an example, the attenuation amount being less than or equal to half means the absolute value of the attenuation amount expressed in dB is less than or equal to half.

As shown in FIG. 4, the series resonator S4 has resonance characteristics including a third attenuation pole ATT3 and a fourth attenuation pole ATT4 each having an attenuation amount less than the attenuation amount of the first attenuation pole ATT1 and a greater attenuation amount than the attenuation amount of the second attenuation pole ATT2.

Further, as shown in FIG. 4, the frequency of the second attenuation pole ATT2 corresponds to the frequency having the smallest attenuation amount between the frequency of the third attenuation pole ATT3 and the frequency of the fourth attenuation pole ATT4.

As shown in FIG. 4, the series resonator S2 has resonance characteristics including a fifth attenuation pole ATT5 and a sixth attenuation pole ATT6 having an attenuation amount less than or equal to half of an attenuation amount of the fifth attenuation pole ATT5. The sixth attenuation pole ATT6 has a higher frequency than those of the first to fifth attenuation poles.

The frequency of the first attenuation pole ATT1 is 935.5 MHz, and the attenuation amount is—26.8 dB.

The frequency of the second attenuation pole ATT2 is 951.6 MHz, and the attenuation amount is—8.2 dB.

The frequency of the third attenuation pole ATT3 is 944.8 MHz, and the attenuation amount is—15.6 dB.

The frequency of the fourth attenuation pole ATT4 is 957.1 MHz, and the attenuation amount is—13.7 dB.

The frequency of the fifth attenuation pole ATT5 is 931.2 MHz, and the attenuation amount is—31.8 dB.

The frequency of the sixth attenuation pole ATT6 is 961.4 MHz, and the attenuation amount is—9.7 dB.

Note that a magnitude relationship of an attenuation amount is described by an absolute value.

The passband of a reception filter 40 is 925 MHz to 960 MHz. The frequencies of the first to fifth attenuation poles are within the passband of the reception filter 40.

FIG. 5 is a figure showing the attenuation characteristics of the acoustic wave device of the first embodiment and a comparative example. The solid line represents the attenuation characteristics of the acoustic wave device according to the first embodiment. The dashed line shows the attenuation characteristics of the acoustic wave device according to the comparative example. The acoustic wave device according to the comparative example is optimized by a conventional design method without employing the present invention, and the size of the device chip and the members used are the same as those of the acoustic wave device according to the first embodiment.

As shown in FIG. 5, it can be seen that the acoustic wave device according to the first embodiment has higher attenuation characteristics than that of the acoustic wave device according to the comparative example because the smallest value of the attenuation amount (absolute value) in the reception pass band (925 MHz to 960 MHz) is larger.

FIG. 6 is a diagram illustrating isolation characteristics of the acoustic wave device according to the first embodiment and the comparative example.

The solid line represents the isolation characteristics of the acoustic wave device according to the first embodiment. The dashed line shows the isolation characteristics of the acoustic wave device according to the comparative example.

As shown in FIG. 6 it can be seen that the acoustic wave device according to the first embodiment has higher isolation characteristics than that of the acoustic wave device according to the comparative example because the smallest value of the attenuation amount (absolute value) in the reception pass band (925 MHz to 960 MHz) is larger.

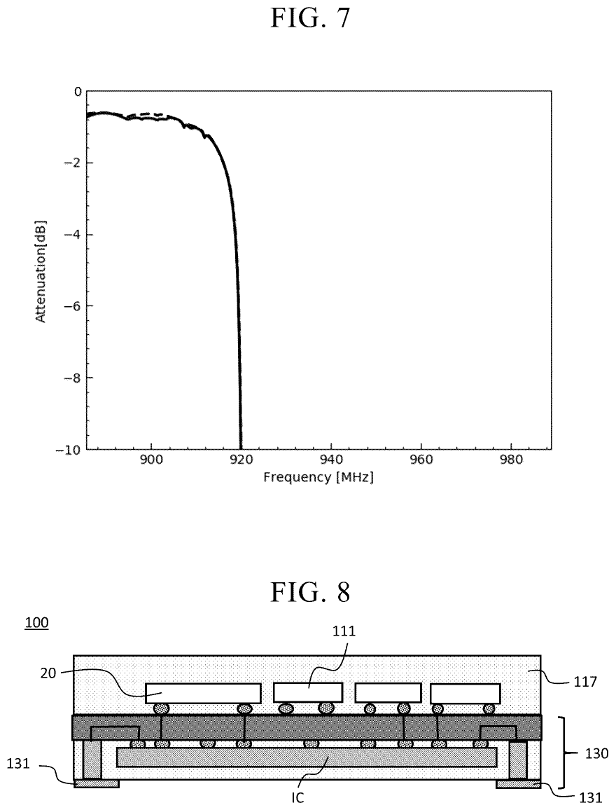

FIG. 7 is a figure showing an insertion loss of the acoustic wave device of first embodiment and the comparative example. The solid line represents the insertion loss of the acoustic wave device in the first embodiment. The dashed line shows the insertion loss of the acoustic wave device according to the comparative example.

As shown in FIG. 7, it can be seen that the insertion loss of the acoustic wave device according to the first embodiment and that of the acoustic wave device according to the comparative example is almost the same.

According to the first embodiment described above, it is possible to provide an acoustic wave device with improved isolation characteristics while ensuring steep characteristics without increasing insertion loss or using an additional element.

### Second Embodiment

FIG. 8 is a longitudinal sectional view of a module to which the acoustic wave device according to a second embodiment is applied. The same or corresponding parts with the first embodiment and second embodiment may be denoted by the same reference numerals. Duplicate descriptions of such portions may be simplified or omitted.

A module 100 includes a wiring substrate 130, a plurality of external connecting terminals 131, an integrated circuit component IC, the acoustic wave device 20, an inductor 111, and a sealing portion 117 in FIG. 8.

The plurality of external connection terminals 131 are formed on the lower surface of the wiring substrate 130. The plurality of external connection terminals 131 are mounted on the motherboard of the mobile communication terminal which is set in advance.

For example, the integrated circuit component IC is mounted inside the wiring substrate 130. The integrated circuit component IC includes a switching circuit and a low noise amplifier.

The acoustic wave device 20 is mounted on the main surface of the wiring substrate 130.

The inductor 111 is mounted on the main surface of the wiring substrate 130. The inductor 111 is mounted for velocity matching. For example, the inductor 111 is Integrated Passive Device (IPD).

The sealing portion 117 seals a plurality of electronic components including the acoustic wave device 20.

The module 100 according to the second embodiment described above includes the acoustic wave device 20. Therefore, it is possible to provide an acoustic wave device with improved isolation characteristics while ensuring steep characteristics without increasing insertion loss or using an additional element.

While several aspects of at least one embodiment have been described, it is to be understood that various modifications and improvements will readily occur to those skilled in the art. Such modifications and improvements are intended to be part of the present disclosure and are intended to be within the scope of the present disclosure.

It is to be understood that the embodiments of the methods and apparatus described herein are not limited in application to the structural and ordering details of the components set forth in the foregoing description or illustrated in the accompanying drawings. Methods and apparatus may be implemented in other embodiments or implemented in various manners.

Specific implementations are given here for illustrative purposes only and are not intended to be limiting.

The phraseology and terminology used in the present disclosure are for the purpose of description and should not be regarded as limiting. The use of “including,” “comprising,” “having,” and variations thereof herein means the inclusion of the items listed hereinafter and equivalents thereof, as well as additional items.

The reference to “or” may be construed so that any term described using “or” may be indicative of one, more than one, and all of the terms of that description.

References to front, back, left, right, top, bottom, and side are intended for convenience of description. Such references are not intended to limit the components of the present disclosure to any one positional or spatial orientation. Accordingly, the foregoing description and drawings are by way of example only.

What is claimed is:

1. An acoustic wave device comprising:
a band pass filter having a plurality of series resonators and a plurality of parallel resonators; and
a first series resonator and a second series resonator which are included in the plurality of series resonators;
wherein the first series resonator has a first attenuation pole and a second attenuation pole, the second attenuation pole has an attenuation amount that is less than or equal to half of an attenuation amount of the first attenuation pole,
the second series resonator has a third attenuation pole and a fourth attenuation pole,
the third attenuation pole and the fourth attenuation pole each has an attenuation amount less than that of the first attenuation pole and greater than that of the second attenuation pole.

2. The acoustic wave device according to claim 1, wherein a frequency of the second attenuation pole is between a frequency of the third attenuation pole and a frequency of the fourth attenuation pole.

3. The acoustic wave device according to claim 2, wherein the frequency of the second attenuation pole corresponds to a frequency having the smallest attenuation amount between the frequency of the third attenuation pole and the frequency of the fourth attenuation pole.

4. The acoustic wave device according to claim 1, further comprising a third series resonator which is included in the plurality of series resonators, wherein the third series resonator has a fifth attenuation pole and a sixth attenuation pole having an attenuation amount that is less than or equal to half of an attenuation amount of the fifth attenuation pole and a frequency of the sixth attenuation pole is higher than frequencies of the first to the fifth attenuation poles.

5. The acoustic wave device according to claim 1, further comprising a second band pass filter, wherein frequencies of the second to the fourth attenuation poles are within a pass band of the second band pass filter.

6. The acoustic wave device according to claim 4, further comprising a second band pass filter, wherein frequencies of the first to the fifth attenuation poles are within a pass band of the second band pass filter.

7. The acoustic wave device according to claim 1, wherein the plurality of series resonators and the plurality of parallel resonators are formed on a piezoelectric substrate.

8. The acoustic wave device according to claim 7, wherein the piezoelectric substrate is a substrate formed of a single crystal of lithium tantalate or lithium niobate.

9. The acoustic wave device according to claim 7, further comprising a support substrate which is bonded to the piezoelectric substrate, wherein the support substrate is a substrate formed of sapphire, silicon, alumina, spinel, quartz or glass.

10. A module comprising the acoustic wave device according to claim 1.
